(19) United States
(12) Patent Application Publication
(10) Pub. No.: US 2015/0325460 A1
(43) Pub. Date: Nov. 12, 2015

(54) ETCHING CHAMBER AND METHOD OF MANUFACTURING SUBSTRATE

(71) Applicant: CANON KABUSHIKI KAISHA, Tokyo (JP)

(72) Inventors: Kenta Furusawa, Yokohama-shi (JP); Shuji Koyama, Kawasaki-shi (JP); Mitsuru Chida, Yokohama-shi (JP); Ryotaro Murakami, Yokohama-shi (JP)

(21) Appl. No.: 14/706,836

(22) Filed: May 7, 2015

(30) Foreign Application Priority Data
May 12, 2014 (JP) 2014-098654

(51) Int. Cl. H01L 21/67; H01L 21/683; H01L 21/306

(52) U.S. Cl. CPC H01L 21/67075; H01L 21/30604; H01L 21/6838

(57) ABSTRACT

An etching chamber includes a chamber body including a flow channel and an opening mounted the substrate to be etched and the opening communicating with the flow channel and a sealing member provided in the periphery of the opening and configured to close a gap between the substrate and the chamber body when the substrate is mounted in the opening, wherein the sealing member includes a first groove provided on an upper surface of the sealing member which comes into abutment with the substrate when the substrate is mounted in the opening, a second groove provided on a sealing member bottom surface on a side opposite from the upper surface of the sealing member, and at least one communicating hole communicating with the first groove and the second groove.

### BACKGROUND

1. Field of the Invention

This disclosure relates to an etching chamber used when etching a substrate by using an etchant, and a method of manufacturing the substrate.

2. Description of the Related Art

With the progress of high level integration of semiconductor apparatuses and high densification of inkjet head nozzles, an increase in the diameter of an aperture of a substrate has taken place. If the substrate has a diameter of 6 inches to 8 inches, a wet etching process is possible even with a batch-type apparatus configured to immerse a plurality of substrate into a bath filled with heated etchant. However, in the case of etching of a substrate exceeding 8 inches or in the case where etching with a higher degree of accuracy is to be performed even when the substrates are 6 inches or 8 inches wide, modification to an apparatus of a sheet-fed type is required.

Japanese Patent Laid-Open No. 2014-67773 describes an example of a sheet-fed type etching apparatus. The etching apparatus includes an etching chamber configured to cause the etchant to come into contact only with a surface of the substrate to be etched (hereinafter, referred to as “etching surface”). The etching chamber is provided with a chamber body which defines a flow channel where the etchant flows, and the chamber body is provided with an opening which communicates with the flow channel formed therein. By flowing the etchant to the flow channel in a state in which the etching surface covers the opening, the etchant comes into contact with the etching surface and etching of the etching surface is achieved. A gap between the chamber body and the substrate is closed by using a sealing member, and the etchant is suppressed from leaking from the gap.

### SUMMARY

This disclosure provides an etching chamber according to an aspect of this disclosure including: a chamber body including a flow channel and an opening which communicates with the flow channel and on which a substrate to be etched is mounted, and a sealing member provided in the periphery of the opening and configured to close a gap between the substrate and the chamber body when the substrate is mounted on the opening, wherein the sealing member includes; a first groove provided on an upper surface of the sealing member which comes into abutment with the substrate when the substrate is mounted on the opening, a second groove provided on a sealing member bottom surface on a side opposite from the upper surface of the sealing member, and at least one communicating hole communicating with the first groove and the second groove.

This disclosure also provides a method of manufacturing a substrate including: attaching a substrate to be etched to an opening provided on a chamber body via a sealing member provided in a periphery of the opening, etching the substrate by flowing an etchant in a flow channel provided in the chamber body and communicating with the opening, and feeding gas to a first groove provided on an upper surface of the sealing member which is in abutment with the substrate via a second groove provided on a sealing member bottom surface on a side opposite from the upper surface of the sealing member, and at least one communicating hole communicating the first groove and the second groove and blowing the gas from the first groove to the substrate.

Further features of the present invention will become apparent from the following description of exemplary embodiments with reference to the attached drawings.

### BRIEF DESCRIPTION OF THE DRAWINGS

FIG. 1 is a schematic drawing of an etching apparatus provided with an etching camber of this disclosure.

FIG. 2 is a front view of the etching chamber of this disclosure.

FIGS. 3A to 3C are a front view and partial cross-sectional views of the etching chamber illustrated in FIG. 2.

FIGS. 4A to 4D are drawings for explaining a sealing member used in a first example.

FIGS. 5A to 5C are drawings for explaining a sealing member used in a second example.

### DESCRIPTION OF THE EMBODIMENTS

In an etching chamber described in Japanese Patent Laid-Open No. 2014-67773, an etchant or a washing liquid remains in the periphery of a sealing member after etching, and a surface tension occurs between a substrate and the etching chamber. Since the substrate is pressed against the sealing member at the time of etching, adhesiveness between the sealing member and the substrate can easily be increased. The etchant is used in a heated state depending on the type of the etchant, and in this case, the adhesiveness of the substrate is increased in comparison with the case of an etchant used at room temperature. From the reasons described above, there is a problem that the substrate cannot be removed easily from the etching chamber after the completion of the etching.

In view of such a problem as described above, it is an object of the present invention to improve separability of the substrate.

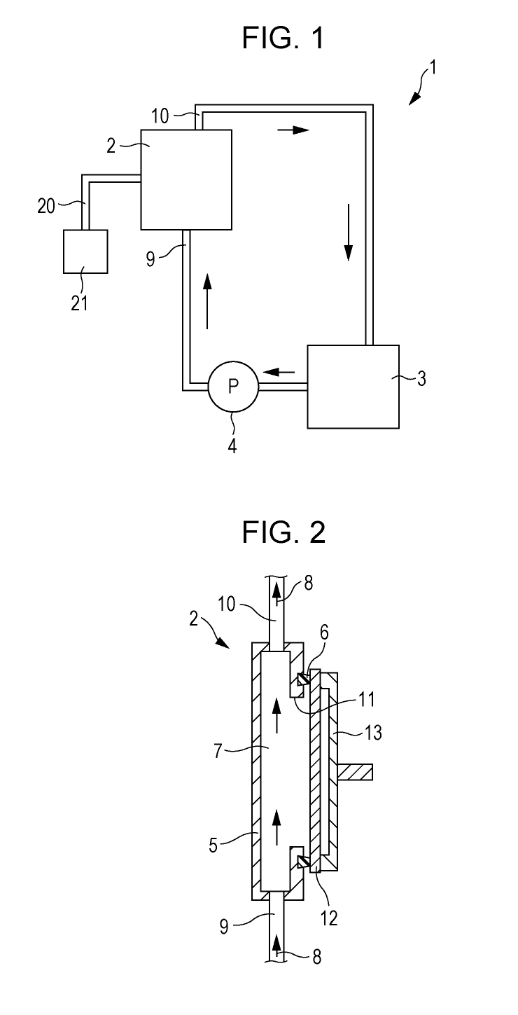

Referring now to the drawings, embodiments of this disclosure will be described. FIG. 1 is a schematic drawing of an etching apparatus provided with an etching camber of this disclosure. As illustrated in FIG. 1, an etching apparatus 1 includes an etching chamber 2, a medical solution bath 3 configured to store an etchant, and a pump 4 configured to pump the etchant from the medical solution bath 3 to the etching chamber 2. The etchant fed to the etching chamber 2 is returned back to the medical solution bath 3 without passing through the pump 4.

FIG. 2 is a cross-sectional view of the etching chamber 2 illustrated in FIG. 1. As illustrated in FIG. 2, the etching chamber 2 includes a chamber body 5 and a sealing member 6. A flow channel 7 is formed in the interior of the chamber body 5. An etching liquid 8 is supplied from a supply pipe 9 to the flow channel 7, and the etching liquid 8 in the flow channel 7 is collected from a collecting pipe 10. The supply pipe 9 is connected to the pump 4 (see FIG. 1), and the collecting pipe 10 is connected to the medical solution bath 3 (see FIG. 1) without the pump 4, which serves as an intermediary.

The chamber body 5 is provided with an opening 11 communicating with the flow channel 7. A substrate 12 to be etched is mounted on the opening 11 by using a substrate retaining mechanism 13, and covers the opening 11. When the etching liquid 8 is supplied to the flow channel 7 in a state in which the substrate 12 is mounted on the opening 11, the flow channel 7 is filled with the etching liquid 8. Consequently, the etching liquid 8 comes into contact with the surface of the substrate 12, and the substrate 12 is etched.

The sealing member 6 is provided in the periphery of the opening 11. More specifically, the sealing member 6 extends along the peripheral edge of the opening 11. In a state in which the substrate 12 is mounted on the opening 11, the sealing member 6 closes a gap between the substrate 12 and the chamber body 5. Since the gap is closed by using the sealing member 6, the etchant 8 is suppressed from leaking from the gap between the substrate 12 and the chamber body 5.

The method of mounting the substrate 12 on the opening 11 is not specifically limited. In order to reduce the stress applied to the substrate 12, the substrate 12 is preferably mounted on the opening 11 while holding the substrate 12 at a side of the substrate opposite to the side where the sealing member 6 exists. In the case where a structure is provided on the substrate 12, the substrate 12 is preferably held in such a manner that the structure is not touched.

In this configuration, the etchant may be made to flow into the inside of the substrate 12 sealed by using the sealing member 6, so that a portion of the substrate 12 which is not covered with a protection resist layer is allowed to be etched. By etching, the substrate 12 can be opened in a depressed shape.

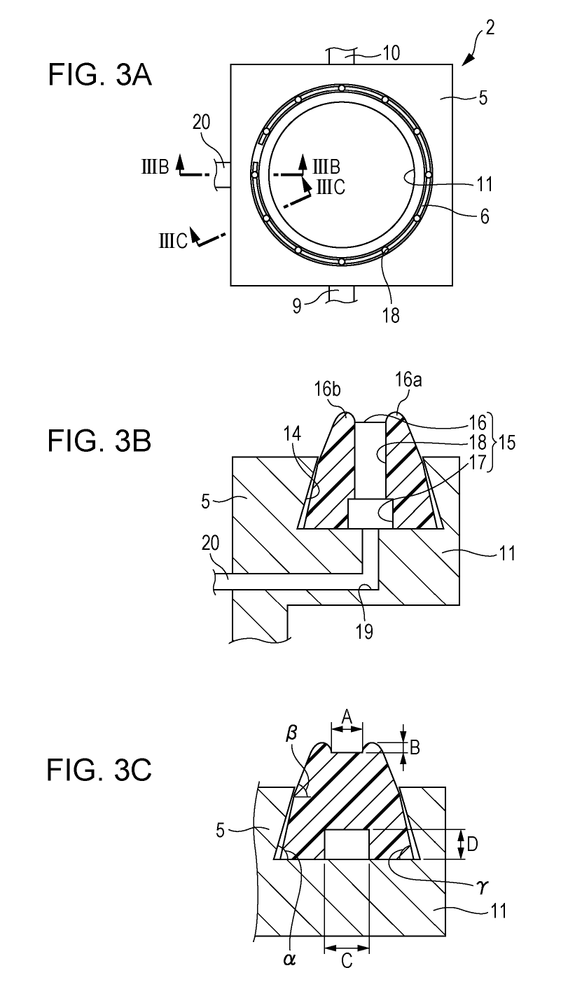

FIG. 3A is a front view (a drawing viewed from the opening 11 toward the flow channel 7) of the etching chamber 2 illustrated in FIG. 2. FIG. 3B is a partial cross-sectional view of the etching chamber 2 taken along a line IIIB-IIIB indicated in FIG. 3A. FIG. 3C is a partial cross-sectional view of the etching chamber 2 taken along the line IIIC-IIIC indicated in FIG. 3A. In FIG. 3A to FIG. 3C, the substrate 12 and a substrate retaining mechanism 13 are not illustrated.

As illustrated in FIG. 3A to FIG. 3C, the chamber body 5 is provided with a sealing groove 14. The sealing member 6 is fitted into the sealing groove 14. Part of the sealing member 6 is protruded from the opening of the sealing groove 14, and the sealing member 6 abuts against the substrate 12 in a state in which the substrate 12 (see FIG. 2) is mounted on the opening 11. By the abutment between the sealing member 6 and the substrate 12, the gap between the chamber body 5 and the substrate 12 is closed, so that the etchant is not likely to leak from the gap.

The sealing member 6 may be any member having resistance characteristics against medicinal solution used as the etching liquid 8 or heat at the time of etching. An abrasion property is preferably higher so as to be capable of using the sealing member 6 repeatedly. From these reasons, the sealing member 6 is preferably a member formed of a material having resistance properties entirely against the medicinal solution and heat (for example, fluorine contained rubber or perfluoroelastomer) than members formed of a material having resistance characteristics only in a part which comes into contact with the medicinal solution and which is subjected to heat.

A side surface of the sealing groove 14 (hereinafter, referred to as a “sealing groove side surface”) is inclined from an opening of the sealing groove 14 (hereinafter, referred to also as a “sealing groove opening”) to a bottom surface of the sealing groove 14 (hereinafter referred to also as a “sealing groove bottom surface”) with respect to a depth direction. More specifically, the sealing groove side surface is inclined so that a groove width is increased as it goes from the sealing groove opening to the sealing groove bottom surface. The groove having such a shape is also referred to as a dovetail groove.

An angle of inclination α of the sealing groove side surfaces with respect to the sealing groove bottom surface is preferably from 40° to 80°, and more preferable from 50° to 70°.

In this specification, the term “groove width” refers to a dimension in a direction intersecting a direction of extension of the groove and a direction of the depth of the groove (hereinafter referred to as a “groove width direction”). For example, the groove width of the sealing groove 14 is a dimension of the sealing groove side surfaces that oppose each other in a lateral direction (the groove width direction) illustrated in FIG. 3B and FIG. 3C.

The sealing member 6 includes a sealing member bottom surface that comes into contact with the sealing groove bottom surface, sealing member side surfaces extending beyond from the sealing member bottom surface to the sealing groove opening, and a sealing member upper surface located on a position opposite to the sealing member bottom surface. The sealing member side surfaces are in contact with part of the sealing groove side surfaces between the sealing groove opening and the sealing groove bottom surface.

The sealing member side surfaces are inclined with respect to the sealing groove bottom surface. The angle of inclination of the sealing member side surfaces with respect to the sealing groove bottom surface is changed from contact portions between the sealing member side surfaces and the sealing groove side surfaces. An angle of inclination γ of the sealing member side surfaces located on the sealing groove bottom surface side with respect to the contact portions is smaller than 80°, and smaller than the angle of inclination α. An angle of inclination β of the sealing member side surfaces located on the sealing groove opening side with respect to the contact portions is larger than 40° and smaller than the angle of inclination γ.

The etching chamber 2 includes a blowing portion 15 provided on the sealing member 6. The blowing portion 15 blows gas (for example, air) toward the substrate 12 retained by the chamber body 5. The blowing portion 15 is preferably capable of sucking the gas.

In this embodiment, the blowing portion 15 includes a first groove 16 formed on the sealing member upper surface, a second groove 17 formed on the sealing member bottom surface, and communicating holes 18 configured to enable the first groove 16 and the second groove 17 to communicate with each other. The first groove 16 is located at a position closer to the sealing member bottom surface than the sealing member upper surface, and the second groove 17 is located at a position closer to the sealing member bottom surface than the first groove 16. In other words, the configuration is such that a single sealing member includes the first groove 16, the second groove 17 and the communicating holes 18, but not such that a plurality of the sealing members each includes the first groove 16, the second groove 17, and the communicating holes 18.

The first and second grooves 16 and 17 extend in the direction of extension of the sealing member 6. The first and second grooves 16 and 17 may be formed over the entire length of the sealing member 6, or the sealing member 6 may include a portion where the first and second grooves 16 and 17 are not formed. As a matter of course, a configuration in which one of the first and second grooves 16 and 17 is formed over the entire length of the sealing member 6, and the other one of those is not formed over the entire length of the sealing member 6.

The number of the communicating holes 18 may be one, but preferably, a plurality of communicating holes 18 are formed in the sealing member 6. More preferably, three to thirty communicating holes 18 are formed in the sealing member 6.

The chamber body 5 is provided with an air ventilation hole 19. One of the openings of the air ventilation hole 19 is formed on the sealing groove bottom surface, and the other opening of the air ventilation hole 19 is formed on one of the side surfaces of the chamber body 5 different from the surface which defines the sealing groove 14. The number of the air ventilation holes 19 may be one, or may be two or more.

The other opening of the air ventilation hole 19 is connected to a suction/blow mechanism 21 (see FIG. 1) via a pipe 20. One of the openings of the air ventilation hole 19 communicates with the second groove 17. Since the second groove 17 communicates with the air ventilation hole 19 in association with an operation of the suction/blow mechanism 21, the gas is fed to the first groove 16 via the pipe 20, the ventilation hole 19, the second groove 17, and the communicating holes 18. The gas is blown out from the first groove 16. In association with the operation of the suction/blow mechanism 21, the gas is sucked from the first groove 16.

In other words, a suction/blow force is transmitted to the second groove 17 via the pipe 20 and the air ventilation hole 19. The force transmitted to the second groove 17 is transmitted to the first groove 16 via the communicating holes 18. Consequently, a force attracting the substrate 12 (see FIG. 2) to the sealing member 6, or a force pushing the substrate 12 away from the sealing member 6 is applied to the substrate 12.

The force attracting the substrate 12 to the sealing member 6 attract the substrate 12 (see FIG. 2) to the sealing member 6. Consequently, displacement of the position of the substrate 12 set in the etching chamber 2 is not likely to occur. The substrate 12 can be separated easily from the sealing member 6 by the force pushing the substrate 12 away from the sealing member 6.

Referring now to FIG. 2 and FIG. 3A to FIG. 3C, liquid may be accumulated in the gap between the substrate 12 and the chamber body 5 after the etching process or the cleaning process. A force attracting the substrate 12 and the chamber body 5 to each other is generated by a surface tension of the liquid. Depending on the method of retaining the substrate 12 or the temperature of the etching liquid 8, the adhesiveness between the substrate 12 and the sealing member 6 may be increased. In association with the action of the surface tension or the increase in adhesiveness, the separability of the substrate 12 with respect to the etching chamber 2 is lowered.

In this embodiment, the gas is blown out from the first groove 16 toward the substrate 12. The gas blown out from the first groove 16 removes the liquid accumulated in the gap between the substrate 12 and the chamber body 5. Consequently, the force between the substrate 12 and the chamber body 5 is reduced, and the separability of the substrate 12 may be improved.

The pressure in the first groove 16 is increased as a result of the gas being fed to the first groove 16. A gap is formed between the sealing member 6 and the substrate 12, and the adhesiveness between the sealing member 6 and the substrate 12 is lowered. Consequently, the separability of the substrate 12 may be improved.

The reason why the first groove 16 communicates with the air ventilation hole 19 via the second groove 17 and a plurality of the communicating holes 18 is that uniformity of the force of the gas applied from the air ventilation hole 19 to the first groove 16 is improved. The reason will be described specifically.

In the case where there is no second groove 17 and the first groove 16 communicates with the air ventilation hole 19 via only one communication hole, the force of the gas acts on the first groove 16 from the air ventilation hole 19 via one communication hole 18, specifically, only on a portion in the vicinity of the communicating holes 18 of the first groove 16.

At the time of suction, at a position away from the communicating holes 18, the substrate 12 is not likely to be attracted by the sealing member 6. Therefore, the gas flows into the first groove 16 from outside of the etching chamber 2, and the force attracting the substrate 12 to the etching chamber 2 is reduced. At the time of blowing, since the force of the gas is applied locally only onto the portions in the vicinity of the communicating holes 18 of the first groove 16, the gas can easily leak from the corresponding portions. Therefore, the force required to push the substrate 12 away from the sealing member 6 is lowered, and the separability is lowered.

The first groove 16 communicates with the air ventilation hole 19 via the second groove 17 and the plurality of the communicating holes 18, so that the force of the gas can easily act on the entire area of the first groove 16. At the time of sucking, the entirety of the substrate 12 is attracted by the sealing member 6. Consequently, the gas is not likely to flow into the first groove 16 from outside of the etching chamber 2, and the force attracting the substrate 12 to the etching chamber 2 is increased. At the time of blowing, the force of the gas acts on the entirety of the first groove 16, and hence the gas is not likely to leak from the first groove 16. Therefore, the force required to push the substrate 12 away from the sealing member 6 is increased, and the separability is improved.

The second groove 17 is provided on the sealing member 6, not on the chamber body 5 (the bottom surface of the sealing groove 14), so that the following effects are achieved.

In other words, in order to form the groove corresponding to the second groove 17 on the chamber body 5 (specifically, the bottom surface of the sealing groove 14), a relatively complex process is required. Therefore, the manufacturing cost of the chamber body 5 is increased, and hence the manufacturing cost of the etching chamber 2 is increased.

The rigidity of the chamber body 5 is decreased as a result of the groove being formed on the bottom surface of the sealing groove 14. In the case where the heated etching liquid 8 is supplied to the flow channel 7, the chamber body 5 is affected by heat, and is deformed markedly. Consequently, when the substrate 12 is set in the etching chamber 2, a gap is formed between the sealing member 6 and the substrate 12, and the sealing property, the attracting property, and the separability are lowered.

A process of forming the second groove 17 on the sealing member 6 is simpler than a process of forming the groove on the bottom surface of the sealing groove 14. Therefore, the manufacturing cost of the sealing member 6 is almost the same in the case of forming the second groove 17 on the sealing member 6 and the case of not forming the second groove 17, and hence an increase of the manufacturing cost of the etching chamber 2 may be suppressed.

Since formation of the groove on the bottom surface of the sealing groove 14 is not necessary, the rigidity of the chamber body 5 may be maintained. Therefore, even though the heated etching liquid 8 is supplied to the flow channel 7, the chamber body 5 is negligibly deformed. Therefore, when the substrate 12 is set in the etching chamber 2, a gap is negligibly formed between the sealing member 6 and the substrate 12, and lowering of the sealing property, the attracting property, and the separability is suppressed.

The second groove 17 may be provided between the first groove 16 and the bottom surface of the sealing groove 14. However, the second groove 17 is preferably formed on the bottom surface (the surface in contact with the bottom surface of the sealing groove 14) of the sealing member 6 when considering the workability of the sealing member 6.

Here, a more preferable shape of the sealing member 6 will be described.

A groove width A of the first groove 16 is the same or the larger than the dimension of the communicating holes 18 in the groove width direction of the first groove 16. In the case where the communicating holes 18 has a column shape, the groove width A is more than the diameter of the column shape.

If the groove width A is too narrow, the first groove 16 is too much collapsed when the substrate 12 is set in the sealing member 6, so that the attraction/separation function cannot work sufficiently. When side walls 16a and 16b which define the first groove 16 are too thin, when the substrate 12 is set to the sealing member 6, the side walls 16a and 16b may fall down, so that the gap between the substrate 12 and the chamber body 5 cannot be closed. From these reasons, the groove width A falls preferably within a range of 40 to 50% and, more preferably, 45% with respect to the dimension of the upper surface of the sealing member 6 in the groove width direction of the first groove 16.

The heights of the two side walls 16a and 16b which define the first groove 16 may be the same or different. The height of an inner side wall 16a located on the opening 11 side of the first groove 16 out of the side walls 16a and 16b is preferably smaller than the height of an outer side wall 16b located on the side opposite to the side of the opening 11 with respect to the first groove 16. More specifically, the inner side wall 16a is preferably lower than the outer side wall 16b in a range from 60 to 140%, and more preferably, lower than 70 to 130% of the amount that the outer side wall 16b is collapsed when the substrate 12 covers the opening 11 via the sealing member 6.

If the first groove 16 is too shallow, the first groove 16 is collapsed too much when the substrate 12 covers the opening 11 via the sealing member 6, so that the attraction/separation function cannot work sufficiently. If the first groove 16 is too deep, the side walls 16a and 16b fall down when the substrate 12 covers the opening 11 via the sealing member 6, and the gap between the substrate 12 and the chamber body 5 cannot be closed. From these reasons, a groove depth B of the first groove 16 is preferable within a range from 0.5 mm to 0.9 mm, and more preferably, within a range from 0.6 mm to 0.8 mm.

In the case where the heights of the inner side wall 16a and the outer side wall 16b are different, the groove depth B is defined to be a dimension from a top of the higher side wall to the bottom surface of the first groove 16.

A groove width C of the second groove 17 is preferably within a range from 30% to 40%, and more preferably, within a range from 33% to 37% with respect to the dimension of the sealing member bottom surface 6 in the groove width direction of the second groove 17. The groove depth D of the second groove 17 is preferably within a range from 20% to 30% and, more preferably, within a range from 23% to 27% with respect to the height of the sealing member 6 (which corresponds to a dimension from the sealing member bottom surface to the sealing member upper surface).

The etching liquid 8 may either be an alkaline solution or an acidic solution. Examples of the alkaline etching liquid 8 include strong alkaline solutions such as tetramethylammonium hydroxide (TMAH), potassium hydroxide (KOH), and sodium hydroxide (NaOH). Examples of the acidic etching 8 include a solution containing ammonium fluoride and ammonium hydrogen fluoride.

The listed solution may be used solely, or two or more types of solution may be mixed. One of more types of additive substances for improving an etching rate may be added to the solution. In the case where the alkaline etching liquid 8 are used, the etching liquid 8 is preferably heated to a range from 40° C. to 98° C., and more preferably heated to a range from 70° C. to 95° C. in order to further improve the etching rate.

The orientation of the etching chamber 2 when setting the substrate 12 to the etching chamber 2 and the direction of setting of the substrate 12 are not specifically limited. For example, the substrate 12 may be set so that the etching surface extends vertically, or so that the etching surface extends horizontally. As a matter of course, the substrate 12 may be set so that the etching surface extends obliquely.

Depending on the types of the etching liquid 8 and the substrate 12, air bubbles may be generated from the substrate 12 at the time of etching. In such a case, the substrate 12 is preferably set in the etching chamber 2 so that the etching surface extends vertically or so that the etching surface faces upward considering the easiness of release of the air bubbles.

### EXAMPLES

This disclosure will be specifically described with reference to First and Second Examples.

### First Example

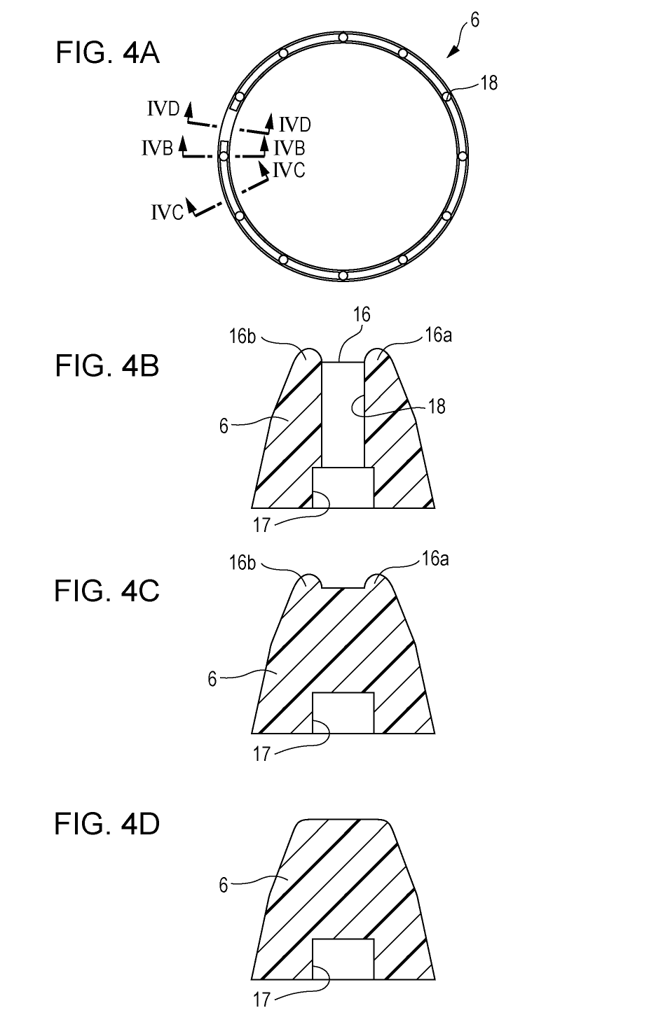

Referring now to FIG. 2 to FIG. 4D, First Example will be described. FIG. 4A is a front view of a sealing member 6 used in an etching chamber 2 according to First Example. FIGS. 4B, 4C, and 4D are partial cross-sectional view of the sealing member 6 taken along the line IVB-IVB, IVC-IVC, and IVD-IVD indicated in FIG. 4A.

A silicon substrate is prepared as a substrate 12 before etching. First of all, a thermoplastic material (Name of Product: HIMAL-1200CH, manufactured by Hitachi Chemical Co., Ltd.) was applied on an etching surface of the silicone substrate by Spin Coat method to form a protection resist layer formed of the thermoplastic material on the etching surface.

Subsequently, a positive-type photosensitive material (Name of Product: THMR-iP5700, manufactured by TOKYO OHKA KOGYO CO., LTD.) was applied on the protection resist layer by Spin Coat method to form a positive type resist layer formed of the positive type photosensitive material on the protection resist layer. Subsequently, part of the positive type resist layer was irradiated with UV light by using an exposure apparatus, and the positive type resist layer is exposed and developed. The positive type resist layer after the development functions as a mask having a desired pattern form.

Subsequently, dry etching was applied on the silicon substrate by using the positive type resist layer as a mask, part of the protection resist layer was removed, and the pattern of the protection resist layer was formed on the etching surface of the silicone substrate. Subsequently, the positive type resist layer which was no longer necessary was removed, and the silicone substrate was set in the etching chamber 2.

An opening width of a sealing groove 14 (which corresponds to a dimension of a sealing groove opening in a groove width direction of the sealing groove 14) was 2.9 mm, the angle of inclination α of the sealing groove side surfaces was 66°, and a groove depth of the sealing groove 14 was 2.8 mm.

As the sealing member 6, an O-ring (Name of Product: DAI-EL™ manufactured by DAIKIN INDUSTRIES, LTD.) formed of perfluoroelastomer was used. A bottom surface width of the sealing member 6 (which corresponds to a dimension of sealing member side surfaces in the groove width direction of the sealing groove 14) was 4.4 mm, an angle of inclination γ of the sealing member side surfaces was 77°, and an angle of inclination β of the sealing member side surfaces was 66°. The height of the sealing member 6 (which corresponds to a dimension from the sealing member bottom surface to the sealing member upper surface) was 3.8 mm. Ten communicating holes 18 of a cylindrical shape having a diameter of 0.9 mm were provided in the sealing member.

The heights of two side walls 16a and 16b of a first groove 16 were set to be almost the same, and a groove depth B of the first groove 16 was 0.7 mm. A groove width A of the first groove 16 was 1.0 mm, which is larger than the diameter of the communicating holes 18.

The first groove 16 was not formed over the entire length of the sealing member 6, and the first groove 16 was not formed in part of the sealing member 6. The length of a portion where the first groove 16 was not formed (which corresponds to a dimension of the sealing member 6 in the extending direction) was 10 mm to prevent liquid from leaking from a notch portion of the substrate 12.

A groove depth D of the second groove 17 was 1.0 mm, and a groove width C of the second groove 17 was 1.5 mm.

A solution containing 22 parts mass of alkaline tetramethylammonium hydroxide (TMAH) was used as an etching liquid 8. The etching liquid 8 was heated up to 83° C. by using a heater (not illustrated), and the etchant was supplied to the etching chamber 2.

When setting the substrate 12 to the etching chamber 2 having the configuration as described above, a suction/blow mechanism 21 (see FIG. 1) was driven to suck air from a pipe 20. The substrate 12 was attracted by the sealing member 6 and the substrate 12 was set without having a positional displacement.

By using the etching chamber 2 and the etching liquid 8 having the configuration as described above, a portion of the substrate 12 surrounded by the sealing member 6 was etched and a portion which was not covered with the protection resist layer was opened in a depressed shape.

In addition, after the etching, the suction/blow mechanism 21 (see FIG. 1) was driven to blow air from a pipe 20, whereby the substrate 12 was separated easily from the etching chamber 2.

### Second Example

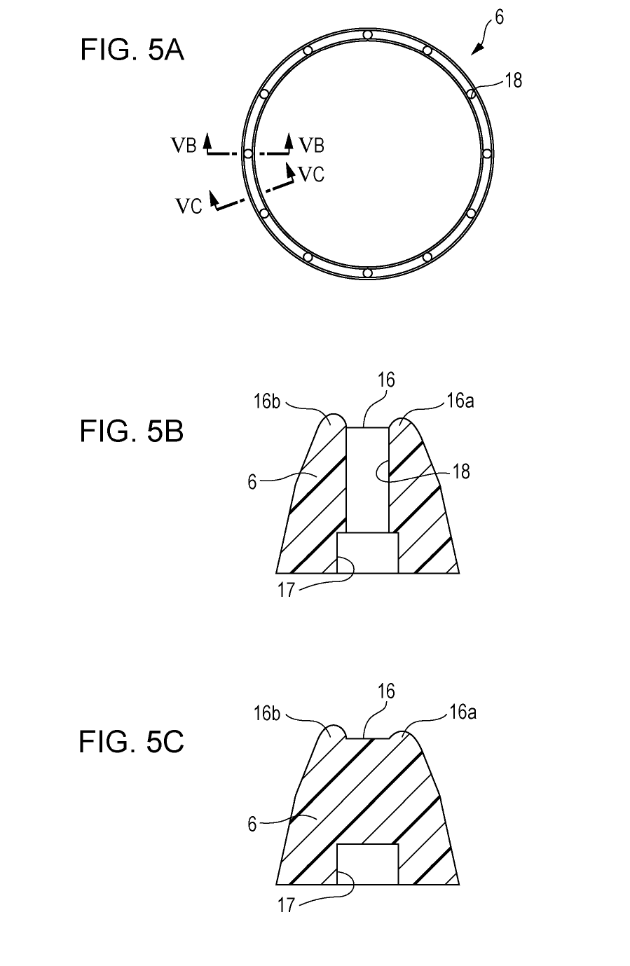

Subsequently, Second Example will be described with reference to FIG. 2, FIGS. 3A to 3C, and FIGS. 5A to 5C. FIG. 5A is a front view of the sealing member 6 used in the etching chamber 2 of Second Example. FIGS. 5B and 5C are partial cross-sectional views of the sealing member 6 the taken along the line VB-VB and VC-VC indicated in FIG. 5A, respectively.

A silicon substrate was prepared as the substrate 12 before etching. First of all, a thermoplastic material (Name of Product: HIMAL-1200CH, manufactured by Hitachi Chemical Co., Ltd.) was applied on an etching surface of the silicone substrate by Spin Coat method to form a protection resist layer formed of the thermoplastic material on the etching surface.

Subsequently, a positive-type photosensitive material (Name of Product: THMR-iP5700, manufactured by TOKYO OHKA KOGYO CO., LTD.) was applied on the protection resist layer by Spin Coat method to form a positive type resist layer formed of the positive type photosensitive material on the protection resist layer. Subsequently, part of the positive type resist layer was irradiated with UV light by using an exposure apparatus, and the positive type resist layer is exposed and developed. The positive type resist layer after the development functions as a mask having a desired pattern form.

Subsequently, dry etching was applied on the silicon substrate by using the positive type resist layer as a mask, part of the protection resist layer was removed, and the pattern which is not covered with the protection resist layer was formed on the etching surface of the silicone substrate. Subsequently, the positive type resist layer which was no longer necessary was removed, and the silicone substrate was set in the etching chamber 2.

An opening width of the sealing groove 14 (which corresponds to a dimension of the sealing groove opening in the groove width direction of the sealing groove 14) was 2.9 mm, the angle of inclination α of the sealing groove side surfaces was 66°, and the groove depth of the sealing groove 14 was 2.8 mm.

As the sealing member 6, an O-ring (Name of Product: DAI-EL™ manufactured by DAIKIN INDUSTRIES, LTD.) formed of perfluoroelastomer was used. The bottom surface width of the sealing member 6 (which corresponds to a dimension of the sealing member side surfaces in the groove width direction of the sealing groove 14) was 4.4 mm, the angle of inclination γ of the sealing member side surfaces was 77°, and the angle of inclination β of the sealing member side surfaces was 66°. The height of the sealing member 6 (which corresponds to a dimension from the sealing member bottom surface to the sealing member upper surface) was 3.8 mm. The ten communicating holes 18 of a cylindrical shape having a diameter of 0.9 mm were provided in the sealing member.

A groove width A of the first groove 16 was 1.0 mm, which is larger than the diameter of the communicating holes 18. The height of the outer side wall 16b of the first groove 16 was 3.8 mm, and the height of the inner side wall 16a was 3.695 mm, which was lower than the height of the outer side wall 16b. The groove depth B of the first groove 16 was 0.7 mm with reference to the height of the outer side wall 16b.

A groove depth D of the second groove 17 was 1.0 mm, and a groove width C of the second groove 17 was 1.5 mm.

A solution containing 22 parts mass of alkaline tetramethylammonium hydroxide (TMAH) was used as the etching liquid 8. The etching liquid 8 was heated up to 83° C. by using a heater (not illustrated), and the etchant was supplied to the etching chamber 2.

When setting the substrate 12 to the etching chamber 2 having the configuration as described above, the suction/blow mechanism 21 (see FIG. 1) was driven to suck air from the pipe 20. The substrate 12 was attracted by the sealing member 6 and the substrate 12 was set without having a positional displacement.

By using the etching chamber 2 and the etching liquid 8 having the configuration as described above, the portion of the substrate 12 surrounded by the sealing member 6 was etched and the portion which was not covered with the protection resist layer was opened in the depressed shape.

In addition, after the etching, the suction/blow mechanism 21 (see FIG. 1) was driven to blow air from the pipe 20, whereby the substrate 12 was separated easily from the etching chamber 2.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-098654, filed May 12, 2014 which is hereby incorporated by reference herein in its entirety.

What is claimed is:

1. An etching chamber comprising:
a chamber body including a flow channel and an opening which communicates with the flow channel and on which a substrate to be etched is mounted, and a sealing member provided in a periphery of the opening and configured to close a gap between the substrate and the chamber body when the substrate is mounted in the opening, wherein
the sealing member includes; a first groove provided on an upper surface of the sealing member which comes into abutment with the substrate when the substrate is mounted in the opening, a second groove provided on a sealing member bottom surface on a side opposite to an upper surface of the sealing member, and at least one communication hole configured to enable the first groove and the second groove to communicate with each other.

2. The etching chamber according to claim 1, wherein
the sealing member includes a plurality of communicating holes, and the first groove and the second groove communicate with each other at a plurality of positions via the plurality of communicating holes.

3. The etching chamber according to claim 1, wherein
a width of a portion communicating with the communicating holes of the first groove in a direction intersecting a direction in which the sealing member extends is equal to or greater than a diameter of the communicating holes.

4. The etching chamber according to claim 1, wherein heights of side walls which define the first groove are different between an inner side wall located on a side of the opening with respect to the first groove and an outer side wall located on a side opposite to the side of the opening with respect to the first groove.

5. The etching chamber according to claim 4, wherein the inner side wall is lower than the outer side wall.

6. The etching chamber according to claim 5, wherein
the inner side wall is lower than the outer side wall within a range from 60 to 140% of an amount of collapse of the outer side wall when the substrate is mounted on the opening.

7. The etching chamber according to claim 1, wherein
the first groove is provided only part of the sealing member in a direction of extension thereof.

8. The etching chamber according to claim 1, wherein
an attraction/separation of the substrate is enabled by performing suction/blowing from the second groove.

9. The etching chamber according to claim 1, wherein a material of the sealing member is perfluoroelastomer.

10. The etching chamber according to claim 1, wherein
acidic or alkaline etchant is made to flow in the flow channel.

11. The etching chamber according to claim 1, wherein
an acidic etchant including ammonium fluoride and ammonium hydrogen fluoride, or at least one of alkaline etchants from among tetramethylammonium hydroxide, potassium hydroxide, and sodium hydroxide is made to flow into the flow channel.

12. A method of manufacturing a substrate comprising:
mounting the substrate to be etched on an opening provided on a chamber body via a sealing member provided in a periphery of the opening;
etching the substrate by making an etchant flow in a flow channel provided in the chamber body and communicating with the opening;
feeding gas to a first groove provided on an upper surface of the sealing member which is in abutment with the substrate via a second groove provided on a sealing member bottom surface on a side opposite from the upper surface of the sealing member, and at least one communicating hole enabling the first groove and the second groove to communicate with each other and blowing the gas from the first groove to the substrate.

13. The method of manufacturing the substrate according to claim 12, wherein
the sealing member includes a plurality of the communicating holes, and gas is fed from the second groove to the first groove via the plurality of the communicating holes.

14. The method of manufacturing the substrate according to claim 12, wherein
gas is sucked from the first groove to attract the substrate to the sealing member when mounting the substrate to be etched on the opening.

15. The method of manufacturing the substrate according to claim 12, wherein
acidic or alkaline solution is used as the etchant when performing etching.

16. The method of manufacturing the substrate according to claim 12, further comprising:
using an acidic etchant including ammonium hydrogen fluoride and ammonium fluoride, or at least one of alkaline etchants from among tetramethylammonium hydroxide, potassium hydroxide, and sodium hydroxide when performing etching.
